(19) United States
(12) Patent Application Publication
(10) Pub. No.: US 2026/0299048 A1
(43) Pub. Date: Oct. 1, 2026

(54) Fault Determination Apparatus and Method for Three-Phase Dual Active Bridge Converter, And Electronic Device

(71) Applicant: XI'AN JIAOTONG-LIVERPOOL UNIVERSITY, Suzhou, Jiangsu (CN)

(72) Inventors: Huiqing WEN, Suzhou, Jiangsu (CN); Shahamat Shahzad KHAN, Suzhou, Jiangsu (CN)

(21) Appl. No.: 18/996,374

(22) PCT Filed: Nov. 2, 2023
(86) PCT No.: PCT/CN2023/129230

§ 371 Date: Jan. 17, 2025

(51) Int. Cl. G01R 31/56

(52) U.S. Cl. CPC G01R 31/56

(57) ABSTRACT

A fault determination apparatus and method for a three-phase dual active bridge converter, and an electronic device. The fault determination apparatus includes a signal acquisition unit and a processing unit. The signal acquisition unit is connected to each of three bridge arm switch node points on a primary side of the three-phase dual active bridge converter and is configured to acquire voltages between two bridge arm switch node points of the three bridge arm switch node points on the primary side. The processing unit is connected to the signal acquisition unit and is configured to determine whether a fault occurs in the three-phase dual active bridge converter according to a relative relationship between a sequence change of the voltages and a normal sequence change.

### CROSS REFERENCE TO RELATED APPLICATION

This is a national stage application filed under 37 U.S.C. 371 based on International Patent Application No. PCT/CN2023/129230, filed on Nov. 2, 2023, disclosure of which is incorporated herein by reference in its entirety.

### TECHNICAL FIELD

Embodiments of the present application relate to power conversion technology, for example, to a fault determination apparatus and method for a three-phase dual active bridge converter, and an electronic device.

### BACKGROUND

The trends of the development of electronic devices to miniaturization, high economy, and diversified function create a new era of electronic devices. The performance of the direct current converter serving as a core power supply component of an electronic device is related to the reliability of the electronic device and the safety of operators.

The fault determination solution for the direct current converter in the related art adopts a sensor to detect fault characteristic parameters. However, such a sensor-based diagnostic method increases the complexity of the power supply component, and the diagnosis speed is slow.

### SUMMARY

The present application provides a fault determination apparatus and method for a three-phase dual active bridge converter, and an electronic device to avoid the processing of a large amount of sensing data and improve the determination speed.

In a first aspect, the embodiments of the present application provide a fault determination apparatus for a three-phase dual active bridge converter. The apparatus includes a signal acquisition unit and a processing unit. The signal acquisition unit is connected to each of three bridge arm switch node points on a primary side of the three-phase dual active bridge converter and is configured to acquire voltages between two bridge arm switch node points of the three bridge arm switch node points on the primary side. The processing unit is connected to the signal acquisition unit and is configured to determine whether a fault occurs in the three-phase dual active bridge converter according to a relative relationship between a sequence change of the voltages and a normal sequence change.

Optionally, the signal acquisition unit includes a respective one of pre-processing units in a one-to-one correspondence with each of the voltages and a respective one of analog-to-digital conversion units in a one-to-one correspondence with each of the voltages. For each pre-processing unit, the pre-processing unit is configured to acquire an analog signal of the respective voltage and pre-process the analog signal. For each analog-to-digital conversion unit, the analog-to-digital conversion unit is separately connected to a respective pre-processing unit and the processing unit and is configured to convert the pre-processed analog signal into a digital signal and send the digital signal to the processing unit.

Optionally, in response to the fault occurring in the three-phase dual active bridge converter, the processing unit is further configured to determine a location where the fault occurs in the three-phase dual active bridge converter according to a relative relationship between the sequence change of the voltages and a fault sequence change, where the fault sequence change corresponds to a controllable switch where the fault occurs.

In a second aspect, the embodiments of the present application further provide a fault determination method for a three-phase dual active bridge converter. The fault determination method includes the following steps: voltages between two bridge arm switch node points on a primary side of the three-phase dual active bridge converter are acquired, and whether a fault occurs in the three-phase dual active bridge converter is determined according to a relative relationship between a sequence change of the voltages and a normal sequence change.

Optionally, the step where whether the fault occurs in the three-phase dual active bridge converter is determined according to the relative relationship between the sequence change of the voltages and the normal sequence change includes the following steps: in response to the sequence of the voltages failing to match the normal sequence change, it is determined that the fault occurs in the three-phase dual active bridge converter, and in response to the sequence of the voltages matching the normal sequence change, it is determined that the fault does not occur in the three-phase dual active bridge converter.

Optionally, the voltages includes a first-second bridge arm voltage, a second-third bridge arm voltage, and a third-first bridge arm voltage. Before whether the fault occurs in the three-phase dual active bridge converter is determined according to the relative relationship between the sequence change of the voltages and the normal sequence change, the method further includes the following step: pre-processing and analog-to-digital conversion processing are performed on an acquired analog signal of the first-second bridge arm voltage to generate a digital signal of the first-second bridge arm voltage; the pre-processing and the analog-to-digital conversion processing are performed on an acquired analog signal of the second-third bridge arm voltage to generate a digital signal of the second-third bridge arm voltage; and the pre-processing and the analog-to-digital conversion processing are performed on an acquired analog signal of the third-first bridge arm voltage to generate a digital signal of the third-first bridge arm voltage.

Optionally, the pre-processing includes attenuation processing, filtering processing, and isolation processing.

Optionally, the normal sequence change includes: a sequential combination of the first-second bridge arm voltage, the second-third bridge arm voltage, and the third-first bridge arm voltage cyclically changes from high-low-zero into high-zero-low, from high-zero-low into zero-high-low, from zero-high-low into low-high-zero, from low-high-zero into low-zero-high, from low-zero-high into zero-low-high, and then into high-low-zero.

Optionally, after whether the fault occurs in the three-phase dual active bridge converter is determined according to the relative relationship between the sequence change of the voltages and the normal sequence change, the method further includes the following step: in response to the fault occurring in the three-phase dual active bridge converter, a controllable switch where the fault occurs is located according to a relative relationship between the sequence change of the voltages and a fault sequence change.

In a third aspect, the embodiments of the present application further provide an electronic device. The electronic device includes at least one processing unit and a memory which is in a communication connection with the at least one processing unit. The memory stores a computer program executable by the at least one processing unit, and the computer program is executed by the at least one processing unit to enable the at least one processing unit to perform the fault determination method for a three-phase dual active bridge converter described in the second aspect.

### BRIEF DESCRIPTION OF DRAWINGS

FIG. 1 is a schematic diagram of the components of a three-phase dual active bridge converter and a fault determination apparatus therefor according to an embodiment of the present application;

FIG. 2 is a schematic diagram of the change in state data of the three-phase dual active bridge converter in a normal operating state according to an embodiment of the present application;

FIG. 3 is a schematic diagram of a normal sequence change of voltages between two bridge arm switch node points according to an embodiment of the present application;

FIGS. 4A-4C is a schematic diagram of changes in the states of multiple controllable switches on the primary side in a cycle process according to an embodiment of the present application;

FIG. 5 is a schematic diagram of the change in state data of the three-phase dual active bridge converter when the normal operating state changes into the fault state according to an embodiment of the present application;

FIG. 6 is a schematic diagram of changes in the states of multiple controllable switches on the primary side after the normal operating state changes into the fault state according to an embodiment of the present application;

FIG. 7 is a state diagram of a sequence change of voltages between two bridge arm switch node points when the normal operating state changes into the fault state according to an embodiment of the present application;

FIG. 8 is another schematic diagram of the components of a fault determination apparatus for a three-phase dual active bridge converter according to an embodiment of the present application;

FIG. 9 is a schematic circuit diagram of a set of pre-processing units and the analog-to-digital conversion circuits each corresponding to a respective one of the pre-processing units in the signal acquisition unit according to an embodiment of the present application;

FIG. 10 is another state diagram of a sequence change of voltages between two bridge arm switch node points when the normal operating state changes into the fault state according to an embodiment of the present application;

FIG. 11 is a waveform diagram of a control signal to the first controllable switch and voltages between two bridge arm switch node points during the normal operation according to an embodiment of the present application;

FIG. 12 is a waveform diagram of a control signal to the first controllable switch and voltages between two bridge arm switch node points when a fault occurs in the first controllable switch according to an embodiment of the present application;

FIG. 13 is a waveform diagram of a control signal to the first controllable switch and an input signal and an output signal of a signal acquisition unit when a fault occurs in the first controllable switch according to an embodiment of the present application;

FIG. 14 is a waveform diagram of multiple signals of the three-phase dual active bridge converter and the fault determination apparatus therefor according to an embodiment of the present application;

FIG. 15 is an enlarged waveform diagram of multiple signals of the three-phase dual active bridge converter and the fault determination apparatus therefor according to an embodiment of the present application;

FIG. 16 is a flowchart of a fault determination method for a three-phase dual active bridge converter according to an embodiment of the present application;

FIG. 17 is another flowchart of a fault determination method for a three-phase dual active bridge converter according to an embodiment of the present application; and

FIG. 18 is a structure diagram of an electronic device that may be used for implementing the embodiments of the present application.

### DETAILED DESCRIPTION

The present application will be described below in conjunction with drawings and embodiments. It is to be understood that the embodiments set forth below are only intended to illustrate the present application, rather than limiting the present application. Additionally, it is also to be noted that for ease of description, only part, not all, of structures related to the present application are illustrated in the drawings.

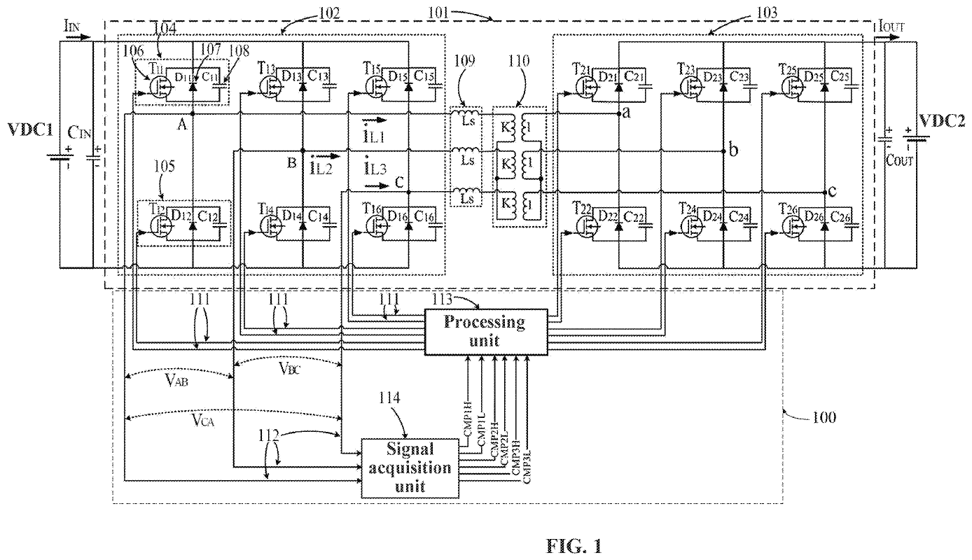

The embodiments of the present application provide a fault determination apparatus for a three-phase dual active bridge converter. FIG. 1 is a schematic diagram of the components of a three-phase dual active bridge converter and a fault determination apparatus therefor according to an embodiment of the present application. With reference to FIG. 1, the fault determination apparatus 100 for a three-phase dual active bridge converter includes a signal acquisition unit 114 and a processing unit 113. The signal acquisition unit 114 is connected to each of three bridge arm switch node points A, B, and C on a primary side of the three-phase dual active bridge converter 101 and is configured to acquire voltages 112 between two bridge arm switch node points of the three bridge arm switch node points on the primary side 102 of the three-phase dual active bridge converter 101. The processing unit 113 is connected to the signal acquisition unit 114 and is configured to determine whether a fault occurs in the three-phase dual active bridge converter 101 according to a relative relationship between a sequence change of the voltages and a normal sequence change.

The three-phase dual active bridge converter 101 is provided with a primary-side bridge 102, an auxiliary inductance combination 109, a voltage-transformation component 110, and a secondary-side bridge 103. The primary-side bridge 102 and the secondary-side bridge 103 are each provided with three bridge arm branches. Each branch includes two switch combinations 104 and 105. Each of the switch combinations 104 and 105 is provided with a controllable switch 106 and an anti-reverse diode 107 which are connected in parallel and also has a parasitic capacitor 108. The processing unit 113 is connected to multiple controllable switches 106 and sends control signals according to the demand to control the on/off of the multiple controllable switches 106, thereby achieving the conversion of the output direct current power supply of the primary side. It should be understood that the signal acquisition unit 114 is also connected to each of three bridge arm switch node points a, b, and c on a secondary side of the three-phase dual active bridge converter 101 through the auxiliary inductance combination 109 and the voltage-transformation component 110.

The bridge arm switch node point refers to a connection point between two switch combinations 104 and 105 on a primary-side bridge arm of the three-phase dual active bridge converter 101. The primary side of the three-phase dual active bridge converter 101 is provided with three bridge arms, which may be defined as a first bridge arm, a second bridge arm, and a third bridge arm, respectively, and then the bridge arm combinations may be a first-second bridge arm, a second-third bridge arm, and a third-first bridge arm, respectively. The signal acquisition unit 114 refers to a signal acquisition and processing component for the voltages 112. The voltages 112 include a first-second bridge arm voltage V_{AB} between the first bridge arm switch node point A and the second bridge arm switch node point B, a second-third bridge arm voltage V_{BC} between the second bridge arm switch node point B and the third bridge arm neutral point C, and a third-first bridge arm voltage V_{CA} between the third bridge arm switch node point C and the first bridge arm switch node point A. The signal acquisition unit 114 is connected to switch node points A, B, and C of the three bridge arm branches on the primary side of the three-phase dual active bridge converter 101 and may acquire the first-second bridge arm voltage V_{AB}, the second-third bridge arm voltage V_{BC}, and the third-first bridge arm voltage V_{CA} and perform data pre-processing.

The processing unit 113 may determine whether a fault occurs in the three-phase dual active bridge converter according to the sequence change of the first-second bridge arm voltage, the second-third bridge arm voltage, and the third-first bridge arm voltage acquired by the signal acquisition unit. The sequence of the above three voltages refers to a sequence of the first-second bridge arm voltage, the second-third bridge arm voltage, and the third-first bridge arm voltage. For example, in the case of the normal sequence change, the sequence combination of the three voltages, that is, the first-second bridge arm voltage, the second-third bridge arm voltage, and the third-first bridge arm voltage, is high-low-zero (that is, the first-second bridge arm voltage is at a high potential, the second-third bridge arm voltage is at a zero potential, and the third-first bridge arm voltage is at a low potential), and then the sequence combination should change into high-zero-low. In the case of an actual sequence change, if the sequence combination of the first-second bridge arm voltage, the second-third bridge arm voltage, and the third-first bridge arm voltage changes from high-low-zero into zero-low-high, then the processing unit may determine that a fault occurs in the three-phase dual active bridge converter. The normal sequence change of the voltages is related to the change of the control signals output from the processing unit to the multiple controllable switches.

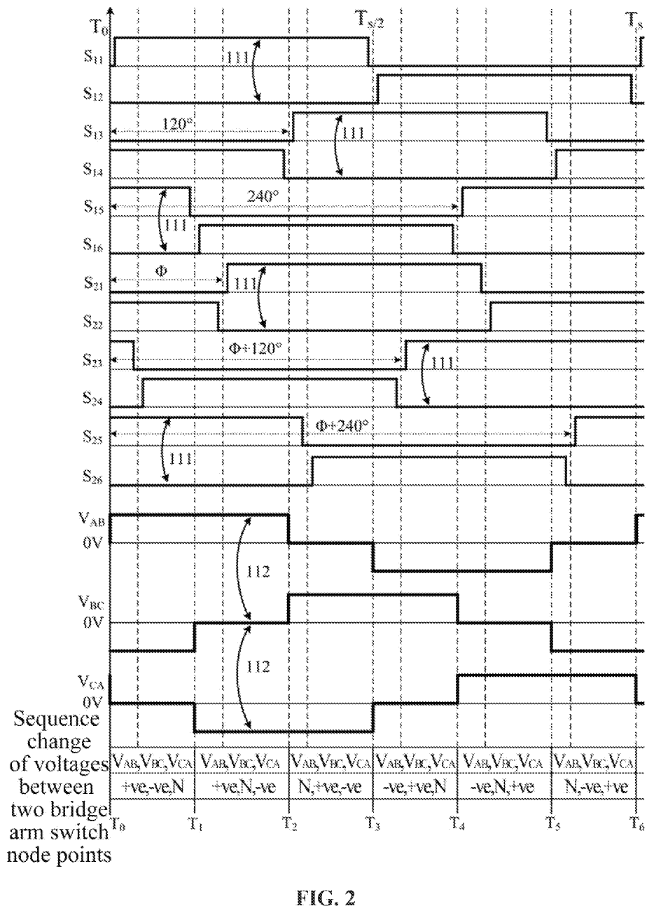

FIG. 2 is a schematic diagram of the change in state data of the three-phase dual active bridge converter in a normal operating state according to an embodiment of the present application. The state data includes the control signals to the multiple controllable switches, the voltages between two bridge arm switch node points, and the sequence of the voltages. In conjunction with FIGS. 1 and 2, S₁₁, S₁₂, S₁₃, S₁₄, S₁₅, and S₁₆ are six control signals 111 output from the processing unit 113 to the primary side and are applied in a one-to-one correspondence to the control terminals of the six controllable switches 106, including the first controllable switch T₁₁, the second controllable switch T₁₂, the third controllable switch T₁₃, the fourth controllable switch T₁₄, the fifth controllable switch Tis, and the sixth controllable switch T₁₆, in the primary-side bridge 102, and S₂₁, S₂₂, S₂₃, S₂₄, S₂₅, and S₂₆ are six control signals output from the processing unit 113 to the secondary side and are applied in a one-to-one correspondence to the control terminals of the six controllable switches 106, including the seventh controllable switch T₂₁, the eighth controllable switch T₂₂, the ninth controllable switch T₂₃, the tenth controllable switch T₂₄, the eleventh controllable switch T₂₅, and the twelfth controllable switch T₂₆, in the secondary-side bridge 102. The controllable switches 106 in the branches operate in an effective and highly complementary mode, and each branch in the primary-side bridge 102 and the secondary-side bridge 103 lags behind the previous one by 120 degrees. The voltage on the second bridge arm lags behind the voltage on the first bridge arm by 120 degrees, and the voltage on the third bridge arm lags behind the voltage on the second bridge arm by 120 degrees and lags behind the voltage on the first bridge arm by 240 degrees. To transmit power from the primary side to the secondary side, the control signal on the secondary side has an added preset phase shift angle compared to the control signal on the primary side, and a negative preset phase shift angle (not shown) may be applied to the reverse power flow.

The first-second bridge arm voltage V_{AB} is the differential voltage on the switch node point A of the first bridge arm branch with respect to the switch node point B of the second bridge arm branch. The second-third bridge arm voltage V_{BC} is the differential voltage on the switch node point B of the second bridge arm branch with respect to the switch node point C of the third bridge arm branch. The third-first bridge arm voltage V_{CA} is the differential voltage on the switch node point C of the third bridge arm branch with respect to the switch node point A of the first bridge arm branch. The three voltages V_{AB}, V_{BC}, and V_{CA} change among a high potential +ve, a low potential −ve, and a zero potential N, and their values are related to the states of the controllable switches 106.

When the three-phase dual active bridge converter 101 is in the normal state, the three switch node voltages V_{AB}, V_{BC}, and V_{CA} cannot share the same level, and the three voltages V_{AB}, V_{BC}, and V_{CA} each have different values at the same time. The sequence of the three voltages V_{AB}, V_{BC}, and V_{CA} repeats after one switch cycle if the sequence is represented in a particular order and the control signal switches normally. A single switch cycle may be divided into six intervals or states according to the change of the control signals. T₀, T₁, T₂, T₃, T₄, T₅, and T₆ represent six times in a switch cycle. In each time sub-interval, the three voltages V_{AB}, V_{BC}, and V_{CA} do not have the same voltage level. When the three-phase dual active bridge converter 101 is in the normal state, the sequence of the three voltages V_{AB}, V_{BC}, and V_{CA} cyclically repeats after each switch cycle.

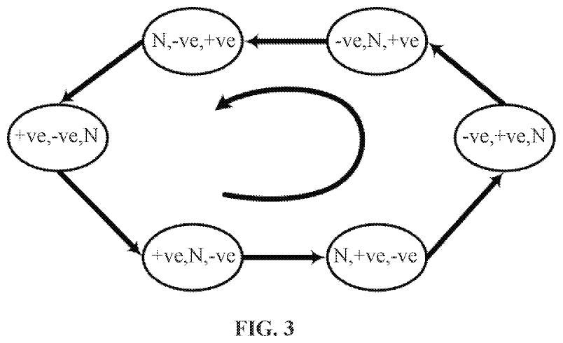

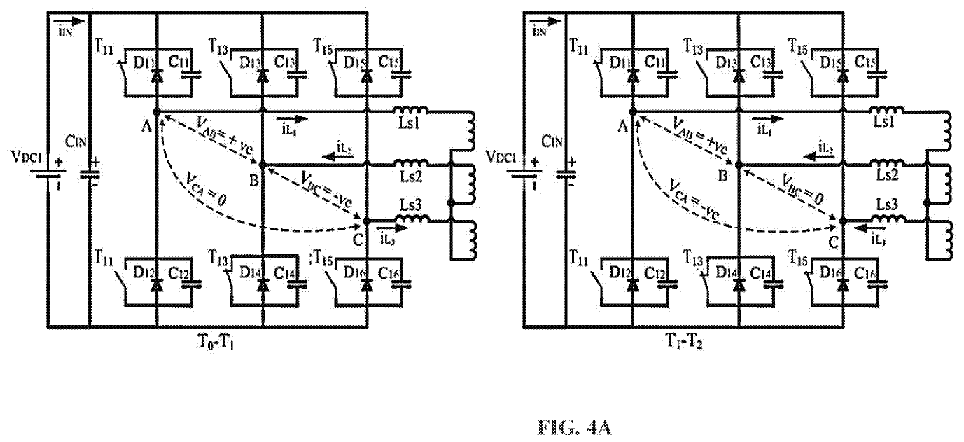

For example, FIG. 3 is a schematic diagram of a normal sequence change of voltages between two bridge arm switch node points according to an embodiment of the present application, and FIG. 4 is a schematic diagram of changes in the states of multiple controllable switches on the primary side in a cycle process according to an embodiment of the present application. FIG. 3 illustrates the cycle process of the voltages between two bridge arm switch node points by using a voltage diagram and a cycle block diagram, and FIGS. 4A-4C illustrates the on/off states of the multiple controllable switches and the current directions on the primary side in multiple intervals in FIG. 3. In conjunction with FIGS. 2, 3, and 4A-4C, during the period from an initial time T₀ to a first time T₁, the sequence of the voltages is high-low-zero, that is, the first-second bridge arm voltage V_{AB} is at a high potential +ve, the second-third bridge arm voltage V_{BC} is at a low potential −ve, and the third-first bridge arm voltage V_{CA} is at a zero potential N. During the period from the first time T₁ to a second time T₂, the sequence of the voltages is high-zero-low, that is, the first-second bridge arm voltage V_{AB} is at a high potential +ve, the second-third bridge arm voltage V_{BC} is at a zero potential N, and the third-first bridge arm voltage V_{CA} is at a low potential −ve. During the period from the second time T₂ to a third time T₃, the sequence of the voltages is zero-high-low, that is, the first-second bridge arm voltage V_{AB} is at a zero potential N, the second-third bridge arm voltage V_{BC} is at a high potential +ve, and the third-first bridge arm voltage V_{CA} is at a low potential −ve. During the period from the third time T₃ to a fourth time T₄, the sequence of the voltages is low-high-zero, that is, the first-second bridge arm voltage V_{AB} is at a low potential −ve, the second-third bridge arm voltage V_{BC} is at a high potential +ve, and the third-first bridge arm voltage V_{CA} is at a zero potential N. During the period from the fourth time T₄ to a fifth time T₅, the sequence of the voltages is low-zero-high, that is, the first-second bridge arm voltage V_{AB} is at a low potential −ve, the second-third bridge arm voltage V_{BC} is at a zero potential N, and the third-first bridge arm voltage V_{CA} is at a high potential +ve. During the period from the fifth time T₅ to a sixth time T₆, the sequence of the voltages is zero-low-high, that is, the first-second bridge arm voltage V_{AB} is at a zero potential N, the second-third bridge arm voltage V_{BC} is at a low potential −ve, and the third-first bridge arm voltage V_{CA} is at a high potential +ve. Then a normal sequence change cycle is completed, and such a cycle process is repeated continuously. The inductor current and the voltages corresponding to each of the six intervals in a cycle are shown in Table 1.

TABLE 1
Cycle data table for the normal sequence change of the
voltages between two bridge arm switch node points

| | Inductor current | | | |
|---|---|---|---|---|
| Interval | i_{L1} | V_{AB} | V_{BC} | V_{CA} |
| T₀-T₁ | i_{L1} = i_{L2} − i_{L3} | +ve | −ve | N |
| T₁-T₂ | i_{L1} = i_{L2} + i_{L3} | +ve | N | −ve |
| T₂-T₃ | i_{L1} = i_{L3} − i_{L2} | N | +ve | −ve |
| T₃-T₄ | i_{L1} = i_{L2} − i_{L3} | −ve | +ve | N |
| T₄-T₅ | i_{L1} = i_{L2} + i_{L3} | −ve | N | +ve |
| T₅-T₆ | i_{L1} = i_{L3} − i_{L2} | N | −ve | +ve |

In summary, when power is transmitted from the primary side to the secondary side, the normal sequence change of the voltages includes that the sequence cyclically changes from high-low-zero into high-zero-low, into zero-high-low, into low-high-zero, into low-zero-high, into zero-low-high, and into high-low-zero. Therefore, the processing unit may store the data of the normal sequence change of the voltages, and if the processing unit judges that the sequence change of the voltages fails to match the normal sequence change, then the processing unit may determine that a fault occurs in the three-phase dual active bridge converter. In addition, when power is transmitted from the secondary side to the primary side reversely, the voltages also match the normal sequence change according to the control signals output from the processing unit, and no further examples will be given herein.

On the basis of obtaining the normal sequence change of the voltages, to explore the sequence change of the voltages in the case where a fault occurs in the three-phase dual active bridge converter, the inventors have made a further study. In the embodiments of the present application, the fault of the three-phase dual active bridge converter is defined as an open-circuit fault occurring in any controllable switch on the primary side of the three-phase dual active bridge converter caused by a fault of the controllable switch or a fault of the driving line of the controllable switch, and the above two faults are simulated by stopping the supply of the control signals to the corresponding controllable switches during the study. For ease of understanding, the following assumptions have been made. 1. Fault determination and fault location analysis have been performed only on the three-phase dual active bridge converter operating in the forward operation mode, and the same analysis is also valid for the reverse flow direction, which will not be repeated herein. 2. Faults are introduced to the controllable switches by stopping the supply of the control signals to the controllable switches. For example, in the case where the controllable switches are field-effect tubes, to simulate the open-circuit fault of the first controllable switch of the first bridge arm, the supply of the control signal to the first controllable switch of the first bridge arm may be stopped. 3. In the case where an open-circuit fault occurs in one controllable switch, it is assumed that no fault occurs in the diode and the parasitic capacitor which are connected to the controllable switch in an antiparallel manner.

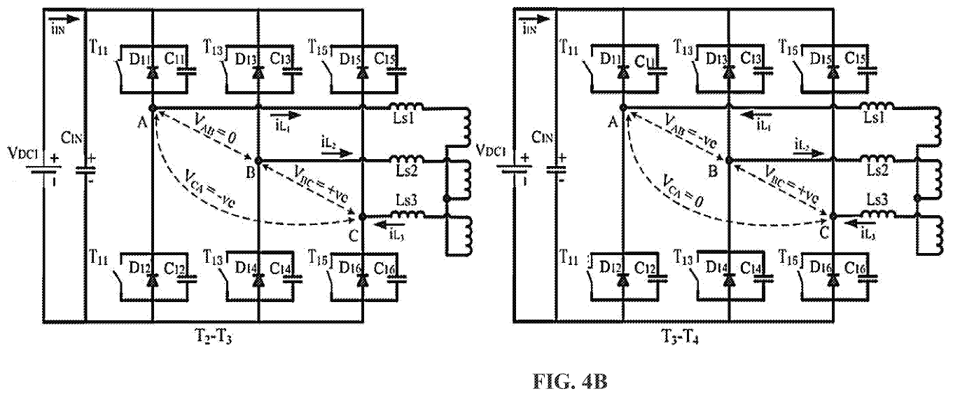

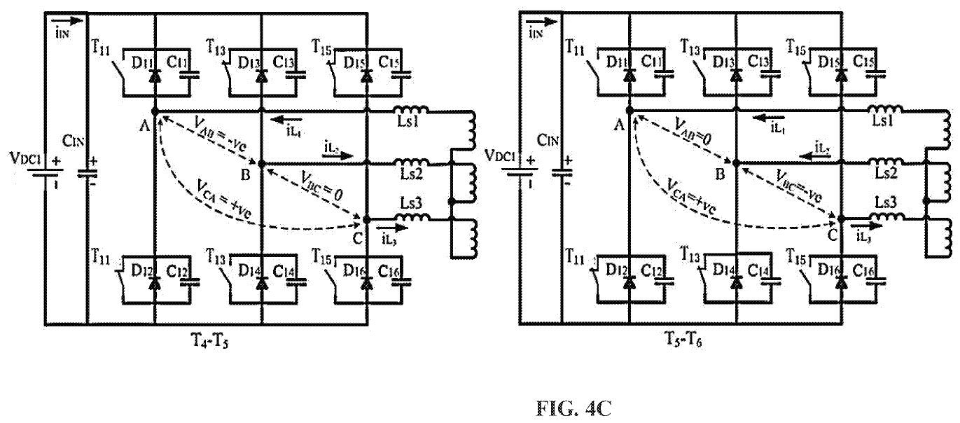

FIG. 5 is a schematic diagram of the change in state data of the three-phase dual active bridge converter when the normal operating state changes into the fault state according to an embodiment of the present application. The state data includes six control signals 111 to the controllable switches, S₁₁, S₁₂, S₁₃, S₁₄, S₁₅, and S₁₆, three inductor currents 115 on the primary side, i_{L1}, i_{L2}, and i_{L3}, the voltages 112 between two bridge arm switch node points, and the sequence of the voltages. FIG. 6 is a schematic diagram of changes in the states of multiple controllable switches on the primary side after the normal operating state changes into the fault state according to an embodiment of the present application. In conjunction with FIGS. 1, 5, and 6, with the case where an open-circuit fault OCF occurs in the first controllable switch T₁₁ on the first bridge arm as an example, the situation on the primary side after the occurrence of the fault is analyzed based on the definitions and assumptions in the embodiments herein to explain the change of the voltages in the multiple fault intervals.

During the period from T₆ to T_{F1}: To simulate the occurrence of an open-circuit fault of the first controllable switch T₁₁ on the first bridge arm, the supply of the control signal S₁₁ to the first controllable switch T₁₁ of the first bridge arm has been stopped during the period from T₅ to T₆. The stopped signal is crossed out with a cross in FIG. 5, and the controllable switch having the fault is also crossed out with a cross in FIG. 6. In accordance with the correct sequence change, the sequence of the voltages is zero-low-high (that is, N, −ve, +ve) during the period from T₅ to T₆. The capacitor C₁₁ corresponding to the first controllable switch T₁₁ is charged to a switch voltage (greater than 0 V), and the capacitor C₁₂ corresponding to the second controllable switch T₁₂ is discharged to 0 V. During the period from T₆ to T_{F1}, only the fourth controllable switch T₁₄ and the fifth controllable switch Tis are on, and the supply of the control signal S₁₁ to the first controllable switch Tu is stopped to simulate the occurrence of an open-circuit of the first controllable switch Tn. During this process, the capacitor Cu corresponding to the first controllable switch T₁₁ is discharged, the capacitor C₁₂ corresponding to the second controllable switch T₁₂ is charged, and the current i_{L1} passing through the first inductor Ls1 must continue to be transmitted in the same negative direction to enable the diode D₁₁ corresponding to the first controllable switch T₁₁ to be on. During the period from T₆ to T_{F1}, the sequence of the voltages changes into high-low-zero (that is, +ve, −ve, N), which matches the normal sequence change. When the current i_{L1} passing through the first inductor Ls1 becomes zero, this interval ends.

During the period from T_{F1} to T_{F2}: During the period from T_{F1} to T_{F2}, the second capacitor C₁₂ corresponding to the second controllable switch T₁₂ is discharged to zero to enable the diode D₁₂ corresponding to the second controllable switch T₁₂ to commutate. The sequence of the voltages changes from high-low-zero (that is, +ve, −ve, N) into zero-low-high (that is, N, −ve, +ve). According to the normal sequence change, the sequence should change from high-low-zero (that is, +ve, −ve, N) into high-zero-low (that is, +ve, N, −ve). In this interval, the sequence change of the voltage does not match the normal sequence change, so the processing unit 113 may determine through this abnormal case whether a fault occurs in the three-phase dual active bridge converter. In addition, after it is determined that a fault has occurred, the processing unit 113 may also determine the location where the fault occurs according to the subsequent sequence change which does not match the normal sequence change, which will be explained in the analysis of the subsequent intervals.

During the period from T_{F2} to T_{F3}: During the period from T_{F2} to T_{F3}, the resonance circuit among the capacitor C₁₁ corresponding to the first controllable switch T₁₁, the capacitor C₁₂ corresponding to the second controllable switch T₁₂, and the first inductor Ls1 enables the diode D₁₁ corresponding to the first controllable switch T₁₁ to commutate and enables the diode D₁₂ corresponding to the second controllable switch T₁₂ to be off. In this manner, the sequence of the voltages changes from zero-low-high (that is, N, −ve, +ve) into high-low-zero (that is, +ve, −ve, N), and the sequence change in this step may be used as the basis for the determination of the location of the fault. The interval from T_{F2} to T_{F3} ends when the fifth controllable switch is switched off and the sixth controllable switch is switched on according to the normal switch of the control signal.

During the period from T_{F3} to T_{F4}: At the beginning of the period from T_{F3} to T_{F4}, because the sixth controllable switch is switched on, the sequence of the voltages changes from high-low-zero (that is, +ve, −ve, N) into high-zero-low (that is, +ve, N, −ve), and the sequence change in this step is the second step and also the final step for determining the location of the fault. If the sequence change of the voltages matches the sequence change in the previous interval and the sequence change in the current interval, the location of the fault occurring in the three-phase dual active bridge converter may be determined as the first controllable switch T₁₁.

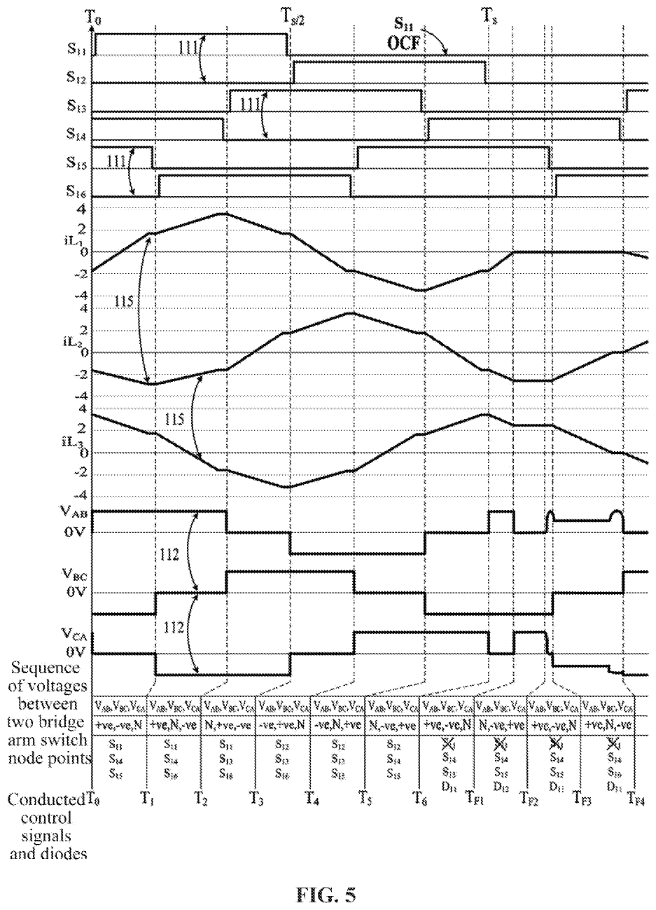

FIG. 7 is a state diagram of a sequence change of voltages between two bridge arm switch node points when the normal operating state changes into a fault state according to an embodiment of the present application. The figure shows a complete state diagram of the normal sequence change and the fault sequence change when a fault occurs in the first controllable switch. With reference to FIG. 7, three types of sequence changes of the voltages after a fault occurs in the first controllable switch may be determined by means of simulation combined with the analysis of the state of the circuit. The six cyclic sequences in the inner circle represent the normal sequence change of the voltages in the case where no fault occurs in the three-phase dual active bridge converter. In the case where an open-circuit fault occurs in the first controllable switch, depending on the time of the occurrence of the fault, there are three types of fault sequence changes of the voltages from the normal region to the fault determination region. These three types of sequence changes are all different from the normal sequence change and may be used for determining whether the fault occurs, which is the first stage of the fault determination procedure.

According to the above simulation results and the circuit analysis, it may be determined that in the case where no fault occurs in the three-phase dual active bridge converter, the sequence of the three voltages cyclically changes according to the normal sequence change. However, after an open-circuit fault is introduced in one of the controllable switches, the sequence change of the three voltages no longer matches the predetermined normal sequence change. In accordance with such a simulation, faults are introduced to multiple controllable switches sequentially. According to the simulation results shown in the figure, it may be found that after an open-circuit fault is introduced to any one of the controllable switches on the primary side, the sequence change of the three voltages no longer matches the predetermined normal sequence change. On this basis, whether a fault occurs in the three-phase dual active bridge converter may be determined according to a relative relationship between the sequence change of the voltages and the normal sequence change.

The fault determination apparatus for a three-phase dual active bridge converter provided by the embodiments of the present application is provided with a signal acquisition unit and a processing unit. The acquisition circuit in the signal acquisition unit is connected to each of the three bridge arm switch node points on the primary side of the three-phase dual active bridge converter and is configured to acquire voltages between two bridge arm switch node points of the three bridge arm switch node points on the primary side of the three-phase dual active bridge converter. The processing unit is connected to the signal acquisition unit and is configured to determine whether a fault occurs in the three-phase dual active bridge converter according to a relative relationship between the sequence change of the voltages and the normal sequence change, thereby achieving the fault determination for the three-phase dual active bridge converter. Since whether a fault occurs is determined by using the voltages in the three-phase active bridge converter, no sensing element is required to be added to the converter, and the data processing function is integrated into the processing unit of the converter, thereby reducing the complexity of the fault determination circuit. Since the fault determination is performed by means of voltages, the processing of a large amount of sensing data can be avoided, thereby improving the determination speed.

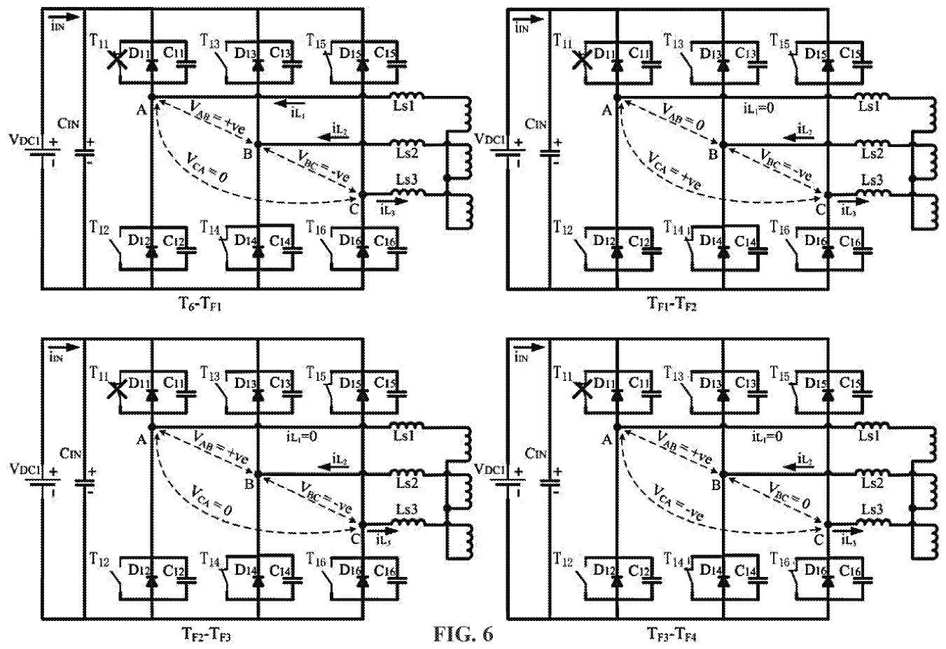

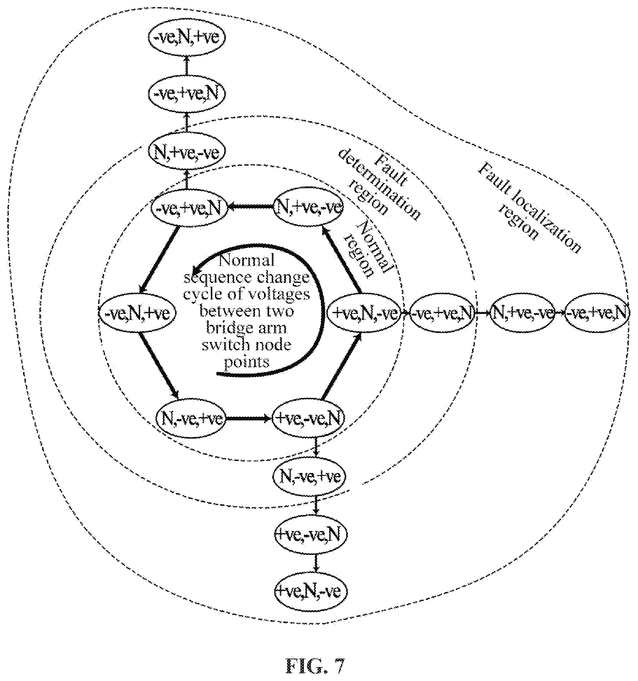

Optionally, FIG. 8 is another schematic diagram of the components of a fault determination apparatus for a three-phase dual active bridge converter according to an embodiment of the present application, and FIG. 9 is a schematic circuit diagram of a set of pre-processing units and the analog-to-digital conversion circuits each corresponding to a respective one of the pre-processing units in the signal acquisition unit according to an embodiment of the present application. On the basis of the preceding embodiments, with reference to FIG. 8, the signal acquisition unit 114 includes pre-processing units 801 and analog-to-digital conversion units 802. For each pre-processing unit 801, the pre-processing unit 801 is configured to acquire an analog signal of a respective one of the voltages and pre-process the analog signal. For each analog-to-digital conversion unit 802, the analog-to-digital conversion unit 802 is separately connected to a respective pre-processing unit 801 and the processing unit 113 and is configured to convert the pre-processed analog signal of the respective voltage into a digital signal and send the digital signal to the processing unit.

The pre-processing unit 801 refers to a circuit component for acquiring and pre-processing the analog signal of the respective voltage. Different function circuits may be provided in the pre-processing unit 801 according to the pre-processing procedures required by the user. For example, the pre-processing may include attenuation processing, filtering processing, isolation processing, and amplification processing. The analog-to-digital conversion unit 802 refers to a conversion circuit capable of converting the pre-processed analog signal of the respective voltage into a digital signal. For example, the digital signal may include a two-bit binary signal. The number of pre-processing units and the number of analog-to-digital conversion units may both be three, and the pre-processing units 801 are in a one-to-one correspondence with the analog-to-digital conversion units 802. Each pre-processing unit 801 is connected to two bridge arm switch node points, and the bridge arm switch node points corresponding to the multiple pre-processing units 801 are not all the same. For example, the first pre-processing unit corresponds to the switch node point of the first bridge arm and the switch node point of the second bridge arm, the second pre-processing unit corresponds to the switch node point of the second bridge arm and the switch node point of the third bridge arm, and the third pre-processing unit corresponds to the switch node point of the third bridge arm and the switch node point of the first bridge arm.

For example, in conjunction with FIGS. 8 and 9, the pre-processing may include attenuation processing, filtering processing, isolation processing, and amplification processing, and correspondingly, each pre-processing unit 801 may include an attenuation circuit 901, a filtering circuit 902, an isolation circuit 903, and an amplification circuit 904. The attenuation circuit 901 is connected to the corresponding two bridge arm switch node points and is configured to introduce and attenuate the analog signal of the voltage between the two bridge arm switch node points (FIG. 9 takes the first-second bridge arm voltage as an example). The filtering circuit 902 is connected to the output terminal of the attenuation circuit 901 and may reduce the amount of noise in the analog signal. The isolation circuit 903 is disposed between the output terminal of the filtering circuit 902 and the input terminal of the amplification circuit 904 and may isolate the analog-to-digital conversion unit 802 of the later stage from the circuit of the preceding stage, thereby preventing the circuit of the later stage from being damaged by a sudden current rush in the circuit of the preceding stage. Each amplification circuit 904 may amplify the analog signal on the secondary side of the isolation circuit 903 to enable the analog signal to be adapted to the range of signals that the analog-to-digital conversion unit 802 of the later stage can process. Each analog-to-digital conversion unit 802 is connected to the output terminal of the amplification circuit 904 and may convert the pre-processed analog signal into a two-bit binary signal. For example, if the two-bit binary signal output by the analog-to-digital conversion unit 802 is 11, it indicates that the voltage corresponding to the analog-to-digital conversion unit 802 is at a high potential; if the two-bit binary signal output by the analog-to-digital conversion unit 802 is 10, it indicates that the voltage corresponding to the analog-to-digital conversion unit 802 is at a zero potential; if the two-bit binary signal output by the analog-to-digital conversion unit 802 is 00, it indicates that the voltage corresponding to the analog-to-digital conversion unit 802 is at a low potential.

Still in conjunction with FIGS. 8 and 9, the attenuation circuit 901 includes two first resistors R₁, two second resistors R₂, and a third resistor R₃ with a variable resistance value, and these resistors are connected in series between two bridge arm switch node points. The voltage dividing effect of the series resistors enables the voltage Vₐₜₜₑₙ between the two output terminals of the attenuation circuit to be smaller than the voltage between the two bridge arm switch node points and thus enables the attenuation circuit to attenuate the voltage to a certain degree, where the degree of attenuation is related to the effective resistance value of the third resistor R₃ in series.

The filtering circuit 902 includes a first amplifier OP1, a second amplifier OP2, a third amplifier OP3, a fourth resistor R₄, two fifth resistors R₅, and four sixth resistors R₆. The first input terminal of the first amplifier OP1 and the first input terminal of the second amplifier OP2 are connected via the fourth resistor R₄, the second input terminal of the first amplifier OP1 and the second input terminal of the second amplifier OP2 are connected to the two output terminals of the attenuation circuit 901, respectively, the output terminal of the first amplifier OP1 is connected via one fifth resistor R₅ to the first input terminal of the first amplifier OP1, and the output terminal of the second amplifier OP2 is connected via another fifth resistor R₅ to the first input terminal of the second amplifier OP2. The first input terminal of the third amplifier OP3 is connected via one sixth resistor R₆ to the output terminal of the first amplifier OP1 and is also connected via another sixth resistor R₆ to the output terminal of the third amplifier OP3. The second input terminal of the third amplifier OP3 is connected via another sixth resistor R₆ to the output terminal of the second amplifier OP2 and is also connected via another sixth resistor R₆ to the ground terminal GND. The output terminal of the third amplifier OP3 is connected via a seventh resistor Rz to one end of the primary-side winding of the isolation circuit 903, and the second input terminal of the third amplifier OP3 is also connected to the other end of the primary-side winding of the isolation circuit 903. The voltage value between the output terminal of the third amplifier OP3 and the ground terminal GND (that is, the two ends of the primary-side winding of the isolation circuit 903) is the filtered voltage V_{diff} of the voltage between the two bridge arm switch node points, and the filtered voltage is based on the ground potential, thereby reducing the data noise of the voltage.

The isolation circuit 903 includes the primary-side winding and a secondary-side winding. The isolation circuit 903 may isolate the current of the primary side from the current of the secondary side and transmit the isolated voltage signal between two bridge arm switch node points through the secondary-side winding. The amplification circuit 904 includes a fourth amplifier OP4, a filter resistor R_{f}, and a filter capacitor C_{f}. The first input terminal of the fourth amplifier OP4 is connected to one end of the secondary-side winding, the second input terminal of the fourth amplifier OP4 is connected to the other end of the secondary-side winding, the output terminal of the fourth amplifier OP4 is connected to one terminal of the filter resistor, and the other terminal of the filter resistor R_{f} is grounded via the filter capacitor C_{f}. The other terminal of the filter resistor R_{f}, as the output terminal of the amplification circuit 904, is also connected to the analog-to-digital conversion unit 802.

The analog-to-digital conversion unit 802 includes a first comparator OP5, a second comparator OP6, and two eighth resistors R₈. The first input terminal of the first comparator OP5 is connected via one eighth resistor R₈ to the output terminal of the amplification circuit 904, the first input terminal of the second comparator is connected via the other eighth resistor to the output terminal of the isolation circuit, the second input terminal of the first comparator OP6 is connected to a first reference potential DAC, and the second input terminal of the second comparator OP6 is connected to a second reference potential DAC Ref2. The output terminal of the first comparator OP5 and the output terminal of the second comparator OP6, as two output terminals of the analog-to-digital conversion unit 802, may each output a converted two-bit binary signal.

The processing unit may be connected to the output terminals of each of the three analog-to-digital conversion units in the signal acquisition unit and access six binary signals. The binary signal of the first-second bridge arm voltage, the binary signal of the second-third bridge arm voltage, and the binary signal of the third-first bridge arm voltage output by the signal acquisition unit are 11, 00, and 10, respectively, and then the processing unit may determine that the first-second bridge arm voltage, the second-third bridge arm voltage, and the third-first bridge arm voltage are high, zero, and low, respectively, and determine, according to the cached data, that the normal sequence change should be that the sequence changes from high-zero-low into high-low-zero. If the next set of binary signals of the first-second bridge arm voltage, the second-third bridge arm voltage, and the third-first bridge arm voltage output by the signal acquisition unit are 11, 10, and 00, respectively, the processing unit may determine that no fault occurs in the three-phase dual active bridge converter 101; otherwise, the processing unit may determine that a fault occurs in the three-phase dual active bridge converter. After the processing operations of the pre-processing unit 113 and the analog-to-digital conversion unit 802, the amount of signal data of the voltages between two bridge arm switch node points is greatly reduced, and the processing unit 113 may complete the comparison of the voltage sequence changes and the fault determination according to the processed binary signals, thereby greatly reducing the amount of data processing.

In the fault determination apparatus for a three-phase dual active bridge converter provided by the embodiments of the present application, the signal acquisition unit includes pre-processing units and analog-to-digital conversion units that are in a one-to-one correspondence with each of the voltages between two bridge arm switch node points. The pre-processing unit is configured to acquire an analog signal of the respective voltage and pre-process the analog signal. The analog-to-digital conversion unit is separately connected to a respective pre-processing unit and the processing unit and is configured to convert a pre-processed analog signal into a digital signal and send the digital signal to the processing unit. In this manner, the voltages between two bridge arm switch node points are pre-processed and converted, thereby facilitating the data analysis of the processing unit of the later stage and further improving the determination reliability of the fault determination apparatus for a three-phase dual active bridge converter.

Optionally, with continued reference to FIG. 8, on the basis of the preceding embodiments, the processing unit 113 is configured to determine, in response to the fault occurring in the three-phase dual active bridge converter 101, a location where the fault occurs in the three-phase dual active bridge converter 101 according to a relative relationship between the sequence change of the voltages and a fault sequence change, where the fault sequence change corresponds to a controllable switch where the fault occurs.

The fault sequence change refers to a preset change of the voltages after a fault occurs in the three-phase dual active bridge converter 101, may be obtained based on experiments or simulation data, and may include a continuous change or multiple changes. After the processing unit 113 determines that the fault occurs in the three-phase dual active bridge converter 101, the processing unit 113 may call up the cached data related to the fault sequence change and determine a fault sequence change matching the sequence change of the voltages, and the controllable switch corresponding to the determined fault sequence change is the controllable switch where the fault occurs. For example, in conjunction with FIGS. 8 and 7, if the sequence change of the voltages matches any one of the three types of fault sequence changes shown in FIG. 7, it may be determined that the fault occurs in the first controllable switch Tu.

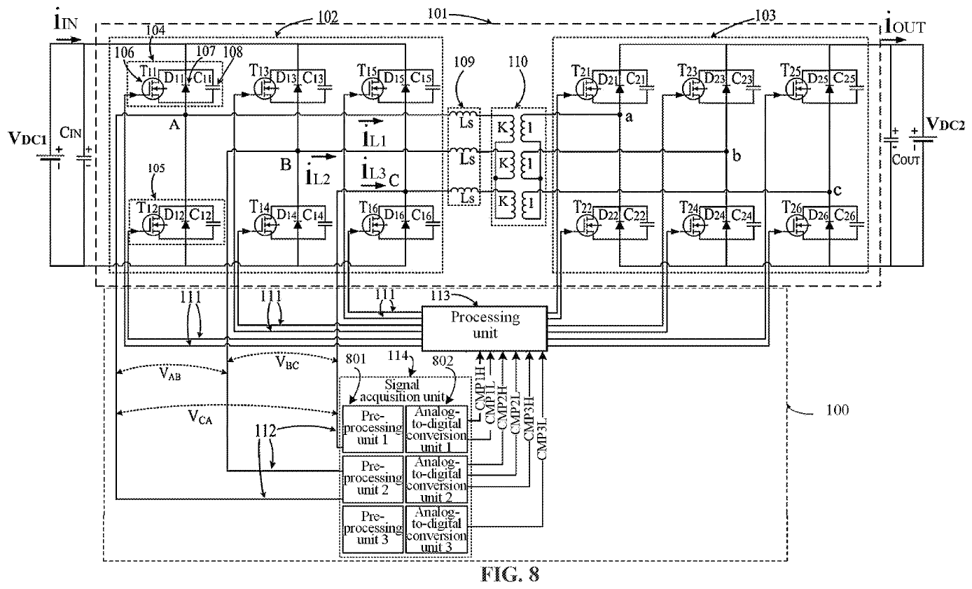

Through simulation and the circuit state analysis, the sequence change of the voltages after multiple controllable switches on the primary side encounter faults may also be determined. FIG. 10 is another state diagram of a sequence change of voltages between two bridge arm switch node points when the normal operating state changes into the fault state according to an embodiment of the present application. The figure shows a complete state diagram of the normal sequence change and the fault sequence change when multiple controllable switches on the primary side encounter faults and also shows the transition of the voltages from the normal sequence change to the fault sequence change due to the fault in each of the multiple different controllable switches. In conjunction with FIGS. 8 and 10, the processing unit 113 may determine whether a fault occurs in the three-phase dual active bridge converter according to whether the sequence change of the voltages matches the normal sequence change. Once the sequence change of the voltages does not match the sequence change in the cycle ring, the sequence change of the voltages follows the sequence change in the fault determination region, and the processing unit 113 may determine that the fault occurs in the three-phase dual active bridge converter. For example, if the sequence of the voltages in the normal cycle changes from zero-low-high into high-low-zero, which matches the normal sequence change, then the processing unit 113 may temporarily determine that no fault occurs in the three-phase dual active bridge converter. However, if the sequence of the voltages in the normal cycle changes from zero-low-high into zero-zero-zero, which does not match the normal sequence change, then the processing unit 113 may determine that the fault occurs in the three-phase dual active bridge converter.

After the processing unit 113 determines that the fault occurs in the three-phase dual active bridge converter, the processing unit 113 may also determine a location where the fault occurs according to a relative relationship between the subsequent sequence change of the voltages and the fault sequence change. All of the fault sequence changes of the three-phase dual active bridge converter during forward power output are illustrated in FIG. 10. For example, if the sequence of the voltages changes into zero-zero-zero, into high-zero-low, and then into high-low-zero, the processing unit 113 may locate the fault location in the fifth controllable switch T₁₅ based on all of the fault sequence changes of the three-phase dual active bridge converter during forward power output.

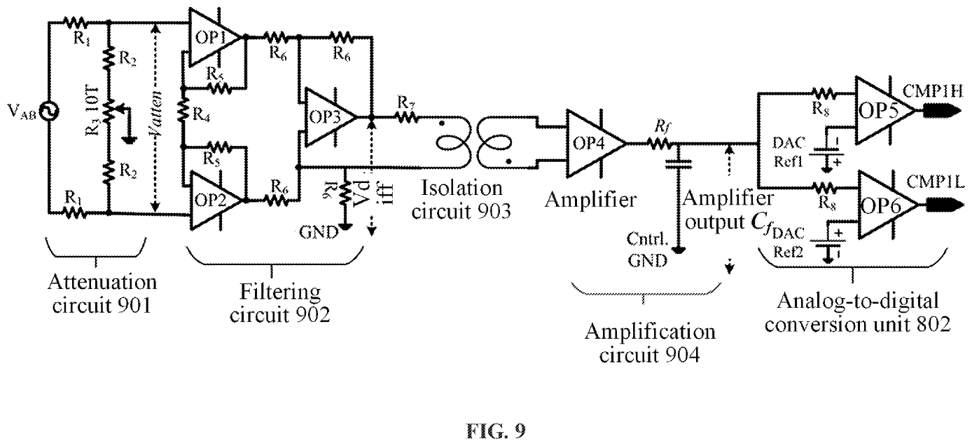

With continued reference to FIG. 10, the voltages, as fault determination signals, have good fault detection and localization characteristics and can be used effectively for fault determination. The state diagram shown in FIG. 10 exemplifies all possible sequence changes of the voltages on the primary side in normal and fault states. In the processing unit 113, both the normal sequence change and the fault sequence change may be stored in a memory in the form of state data. Therefore, when the current sequence change of the voltages is known, the processing unit 113 may compare the current sequence change of the voltages with the normal sequence change in the state data to determine whether a fault occurs. The normal sequence change only includes six changes that are repeated in a specific order. Based on the memory data and the current sequence change of the voltages, the processing unit may determine the correct sequence change that is supposed to appear subsequently and all possible fault sequence changes. For example, the three voltages between two bridge arm switch node points, that is, the first-second bridge arm voltage, the second-third bridge arm voltage, and the third-first bridge arm voltage, may be represented by a high potential +ve, a low potential −ve or a zero potential N. The sequence of the voltages is high-low-zero (that is, +ve, −ve, N). According to the sequence change state diagram shown in FIG. 11, the sequence of the voltages may change in three possible ways. If the sequence of the voltages changes into high-zero-low (that is, +ve, N, −ve), the processing unit may determine that no fault occurs in the three-phase dual active bridge converter. However, if the sequence of the voltages changes into zero-zero-zero (that is, N, N, N) or zero-low-high (that is, N, −ve, +ve), the processing unit 113 may determine that a fault occurs in the three-phase dual active bridge converter. Further, in one aspect, if the sequence of the voltages changes from high-zero-low (that is, +ve, N, −ve) into zero-zero-zero (that is, N, N, N), the processing unit 113 may directly determine that the fault occurs in the fourth controllable switch T₁₄. The sequence of the voltages subsequently changes into zero-high-low (that is, N, +ve, −ve) and then into high-zero-low (that is, +ve, N, −ve). In another aspect, if the sequence of the voltages changes from high-low-zero (that is, +ve, −ve, N) into zero-low-high (that is, N, −ve, +ve), then there may be two possible localization results. The first possible result may be that, if the sequence of the voltages then changes from zero-low-high (that is, N, −ve, +ve) into zero-high-low (that is, N, +ve, −ve), the processing unit may determine that the fault occurs in the second controllable switch T₁₂. The second possible result may be that, if the sequence of the voltages changes from zero-low-high (that is, N, −ve, +ve) into high-low-zero (that is, +ve, −ve, N), then the processing unit may determine that the fault occurs in the first controllable switch T₁₁, and the sequence of the voltages may subsequently change into high-zero-low (that is, ve, N, −ve). Through such a comparison manner, the processing unit 113 can quickly and accurately determine the location of the fault regardless of which controllable switch on the primary side fails.

In the fault determination apparatus for a three-phase dual active bridge converter provided by the embodiments of the present application, the processing unit is also used for determining, in response to the fault occurring in the three-phase dual active bridge converter, a location where the fault occurs in the three-phase dual active bridge converter according to a relative relationship between the sequence change of the voltage and the fault sequence change, thereby achieving the rapid localization of the fault and reducing the difficulty of the subsequent overhaul.

To test the feasibility of the fault determination and localization mechanism in the fault determination apparatus for a three-phase dual active bridge converter, a hardware prototype for the three-phase dual active bridge converter and the fault determination apparatus therefor is developed according to the design specifications given in Table 2.

TABLE 2
Parameter design table for the hardware prototype
of the three-phase dual active bridge converter

| No. | Parameter | Value |
|---|---|---|
| 1 | Power | 100 W |
| 2 | Working frequency | 20 kHz (50 μs) |
| 3 | Input voltage | 50 V |
| 4 | Inductance | 45 μH |

In conjunction with FIG. 9, the first-second bridge arm voltage, the second-third bridge arm voltage, and the third-first bridge arm voltage are extracted from the three bridge arm switch node points on the primary side. The main purpose of the circuit shown in FIG. 9 is to attenuate, isolate, and convert the corresponding voltage (the first-second bridge arm voltage V_{AB} is shown in the figure) into a binary digital signal to be represented. The above voltages are high-voltage analog signals that cannot be fed directly to the processing unit and need to be processed by attenuation, isolation, and analog-to-digital conversion. The attenuation circuit attenuates the high-voltage analog signal into a low-voltage analog signal. The filtering circuit removes the noise from the low-voltage analog signal. The isolation circuit then provides current isolation for the circuits on both sides and feeds the isolated signal to the amplification circuit and then to the analog-to-digital converter circuit. Finally, the analog-to-digital converter circuit outputs a two-bit binary signal (the binary signal, CMP1H and CMP1L, corresponding to the first-second bridge arm voltage V_{AB} is shown in the figure). Table 3 gives the solution for converting the first-second bridge arm voltage V_{AB} to the binary signal. The analog signals of the voltages extracted from the three-phase dual active bridge converter are converted to two-bit binary signals. Therefore, the three voltages of the three-phase dual active bridge converter are converted into a six-bit binary signal, and the processing unit performs analysis and processing using these signals.

TABLE 3
Table of the solution for converting the first-second
bridge arm voltage V_{AB} to the binary signal

| Switch node voltage | CMP1H (Bit1) | CMP1L (Bit0) |
|---|---|---|
| +ve | 1 | 1 |
| −ve | 0 | 0 |
| N | 1 | 0 |

FIG. 11 is a waveform diagram of a control signal to the first controllable switch and three voltages between two bridge arm switch node points during the normal operation according to an embodiment of the present application. The waveforms are normal waveforms extracted from the hardware prototype for the three-phase dual active bridge converter. The horizontal axis is the time, and the vertical axis is the voltage value. In conjunction with FIG. 11, the waveform of the control signal S₁₁ to the first controllable switch is shown at the top, and the following three waveforms are sequentially the waveforms of the three voltages V_{AB}, V_{BC}, and V_{CA}, respectively. The second-third bridge arm voltage V_{BC} lags behind the first-second bridge arm voltage V_{AB} by 120 degrees, and third-first bridge arm voltage V_{CA} lags behind the second-third bridge arm voltage V_{BC} by 120 degrees. The normal voltage cyclically changes from a high potential into a zero potential and then into a low potential.

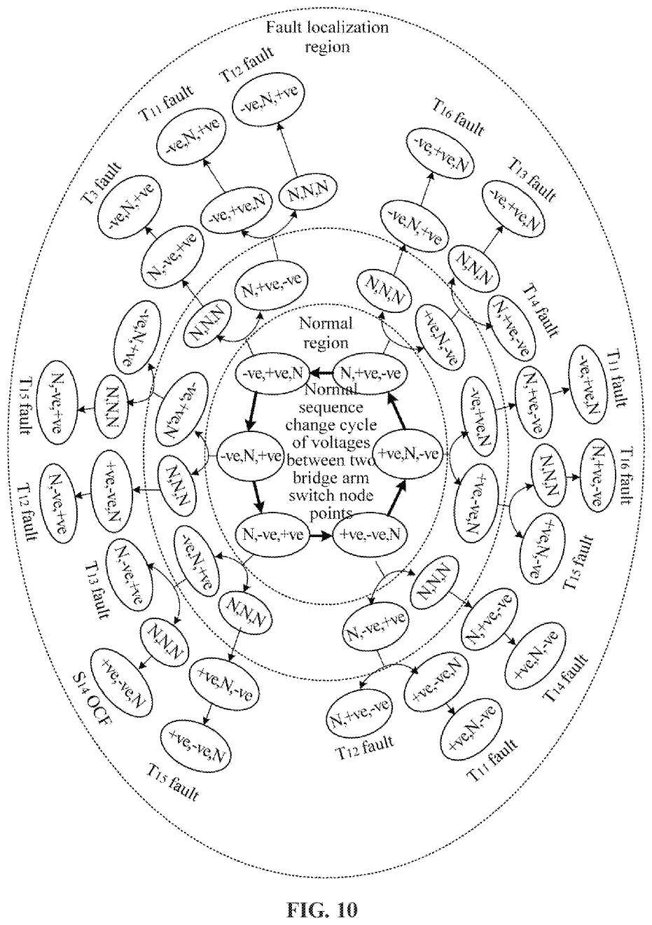

FIG. 12 is a waveform diagram of a control signal to the first controllable switch and three voltages between two bridge arm switch node points when a fault occurs in the first controllable switch according to an embodiment of the present application. In conjunction with FIG. 12, the waveform of the control signal S₁₁ to the first controllable switch is shown at the top, and the following three waveforms are sequentially the waveforms of the three voltages V_{AB}, V_{BC}, and V_{CA}, respectively. After a fault occurs in the first controllable switch (that is, after the supply of the control signal S₁₁ is stopped), it may be detected that two of the three voltages V_{AB}, V_{BC}, and V_{CA} abnormally change. The fault is indicated by the symbol OCF in the diagram. The voltages V_{AB}, V_{BC}, and V_{CA} are fed to the signal acquisition unit, and the signal acquisition unit performs pre-processing including attenuation and isolation on the voltages and then converts the voltages into binary signals using the analog-to-digital conversion circuit. Each voltage is represented by using a two-bit binary signal.

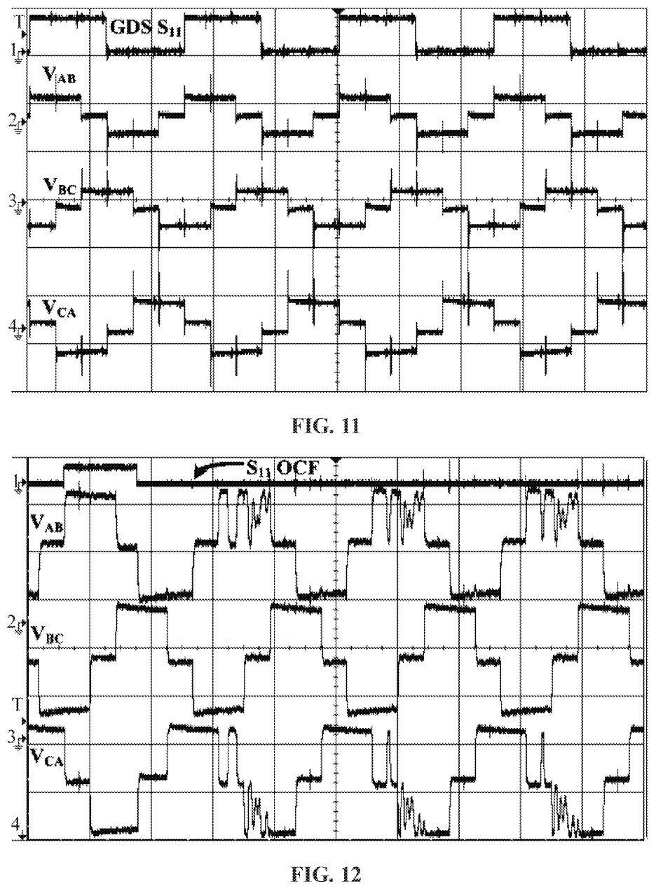

FIG. 13 is a waveform diagram of a control signal to the first controllable switch and an input signal and an output signal of a signal acquisition unit when a fault occurs in the first controllable switch according to an embodiment of the present application. In conjunction with FIG. 13, the waveform at the top is the waveform of the control signal S₁₁ to the first controllable switch; the second and the third waveforms are the waveforms of CMP1H and CMP1L, the binary output signal output after the signal acquisition unit processes the first-second bridge arm voltage V_{AB}; and the waveform at the bottom is the waveform of the input signal of the first-second bridge arm voltage V_{AB} acquired by the signal acquisition unit, which is also the waveform of the first-second bridge arm voltage V_{AB}. In the normal working state, the first-second bridge arm voltage V_{AB} is normal, and the binary signal, CMP1H and CMP1L, output by the signal acquisition unit is also normal. However, when an open-circuit fault occurs in the first controllable switch T₁₁, the first-second bridge arm voltage V_{AB} and the corresponding binary signal, CMP1H and CMP1L, also become abnormal. Similarly, the three voltages may be converted to a six-bit binary signal and then output. Table 4 shows the three voltages V_{AB}, V_{BC}, and V_{CA} and their corresponding binary output signals.

TABLE 4
Table of voltages V_{AB}, V_{BC}, and V_{CA} and
their corresponding binary output signals

| Voltage | Output signal from the signal acquisition unit | |
|---|---|---|
| V_{AB} | CMP1H (Bit1) | CMP1L (Bit0) |
| V_{BC} | CMP2H (Bit1) | CMP2L (Bit0) |
| V_{CA} | CMP3H (Bit1) | CMP3L (Bit0) |

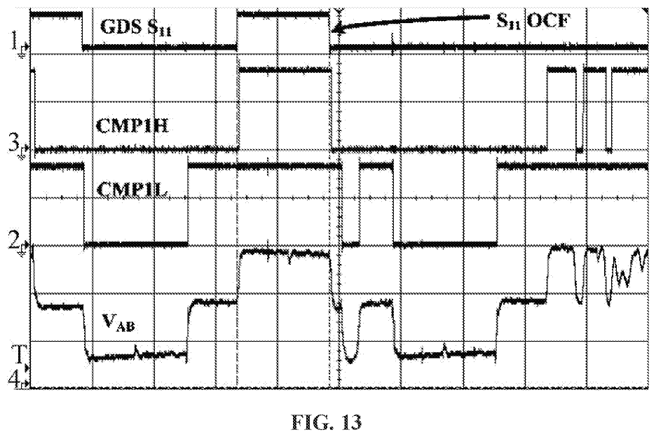

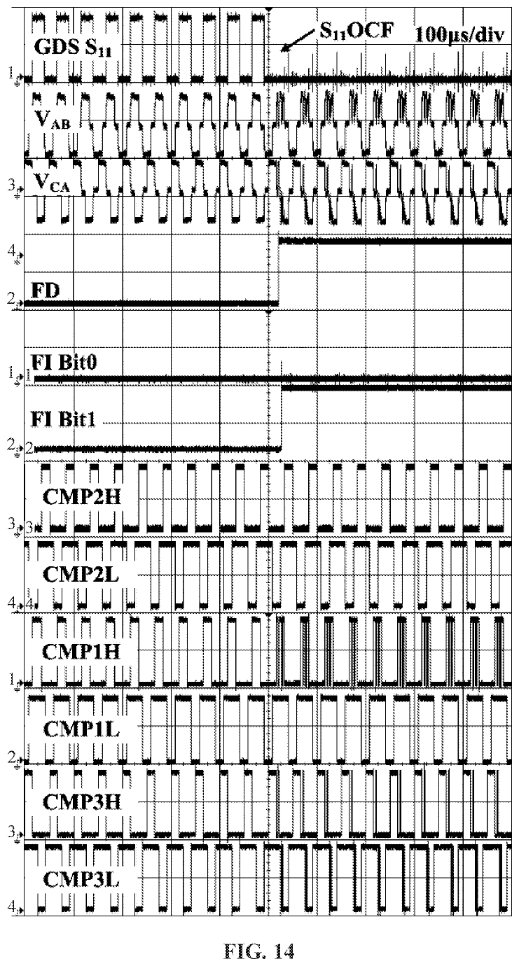

FIG. 14 is a waveform diagram of multiple signals of the three-phase dual active bridge converter and the fault determination apparatus therefor according to an embodiment of the present application, and FIG. 15 is an enlarged waveform diagram of multiple signals of the three-phase dual active bridge converter and the fault determination apparatus therefor according to an embodiment of the present application. Each unit cell of the horizontal axis in FIG. 14 represents 100 μs, and each unit cell of the horizontal axis in FIG. 15 represents 5 μs. FIG. 15 is an enlarged version of the waveform in FIG. 14 and can more clearly illustrate the performance of the fault determination mechanism in terms of accuracy and detection speed. In conjunction with FIGS. 14 and 15, the supply of the control signal S₁₁ to the first controllable switch is stopped to simulate a fault occurring in the first controllable switch. The abnormality of the first-second bridge arm voltage V_{AB} and the third-first bridge arm voltage V_{CA} causes a deviation in the binary signal, CMP1H and CMP1L, corresponding to the first-second bridge arm voltage V_{AB} and a deviation in the binary signal, CMP3H and CMP3L, corresponding to the third-first bridge arm voltage V_{CA}. Because the second-third bridge arm voltage V_{BC} is not affected by the fault in the first controllable switch, the binary signal, CMP2H and CMP2L, corresponding to the second-third bridge arm voltage V_{BC} is not affected. The six-bit binary signal, CMP1H, CMP1L, CMP2H, CMP2L, CMP3H, and CMP3L, is fed to the processing unit for final determination, and the determination result is output in the form of a fault determination signal FD and a two-bit fault localization signal, FI bit0 and FI bit1. The fault determination signal FD is output at a high level after the fault has occurred for 1.8 μs to indicate the presence of a fault. The fault localization signal, FI bit0 and FI bit1, indicates the fault location in the form of a two-bit binary signal. Multiple fault localization signals may be set according to requirements to indicate whether faults occur in all controllable switches. Table 5 shows the meaning of the two-bit fault localization signals.

TABLE 5
Meaning table of fault localization signals

| | First bit | Second bit |
|---|---|---|
| | of the fault | of the fault |
| | localization | localization |
| Fault indication information | signal | signal |
| No fault | 0 | 0 |
| Open-circuit fault in the first | 1 | 0 |
| controllable switch | | |
| Open-circuit fault in the | 0 | 1 |
| second controllable switch | | |
| Open-circuit fault in the third | 1 | 1 |
| controllable switch | | |

FIG. 15 also shows that the time taken to localize the fault is 7.4 μs. The processing unit may implement the determination, localization, and indication of open-circuit faults by means of an electronic processor. The electronic processor may be at least one of a microcontroller, a microprocessor, a field-programmable gate array (FPGA), a digital signal processor, a programmable gate array, a thematic logic unit, a Boolean logic unit, an electronic logic circuit, a digital circuit, a special-purpose integrated circuit, or any other data processing apparatus. In an embodiment, the electronic processor may also execute software instructions stored in a data storage device.

The embodiments of the present application provide a fault determination apparatus for a three-phase dual active bridge converter. The voltages between two bridge arm switch node point is signals used for fault determination, and the existence of a fault can be effectively determined according to the deviation of the sequence change of the voltages from the normal sequence change within a switch cycle. The fault determination process is implemented within 1.8 μs, and the time taken for the fault determination is less than 1/25 of the switch cycle. The accurate localization of the faulty switch is implemented within 7.4 μs, which is less than ⅙ of the switch cycle. Therefore, the fault determination apparatus provided by the present application is extremely fast in detecting the fault, which is very important for the early fault determination of the three-phase dual active bridge converter, and thus can protect the rest of the converter from the long-term impact of the open-circuit fault, such as the asymmetry of the inductor currents, the voltages, and inductor voltages, which may cause current overshoot, voltage imbalance of capacitors, and saturation of magnetic elements and thus affects the reliability and safety of the three-phase dual active bridge converter under long-term operation.

In addition, the fault determination apparatus provided by the present application does not require additional sensors to detect the fault characteristics because the voltages can be tapped directly from the switch node points on the primary side of the three-phase dual active bridge converter and fed to the signal acquisition unit for further data processing, which means that the fault determination apparatus for a three-phase dual active bridge converter provided by the present application can be added to the three-phase dual active bridge converter in the related art without any hardware modification. The processing unit, in combination with the low-cost operational amplifier circuit and resistor network in the signal acquisition unit, can convert the voltages into two-bit binary signals by using a simple comparator circuit as an analog-to-digital conversion unit, without complex signal processing such as shifting, averaging or transforming. The binary signals can accurately represent the voltages in real time and can be used for final fault determination and fault localization in the processing unit.

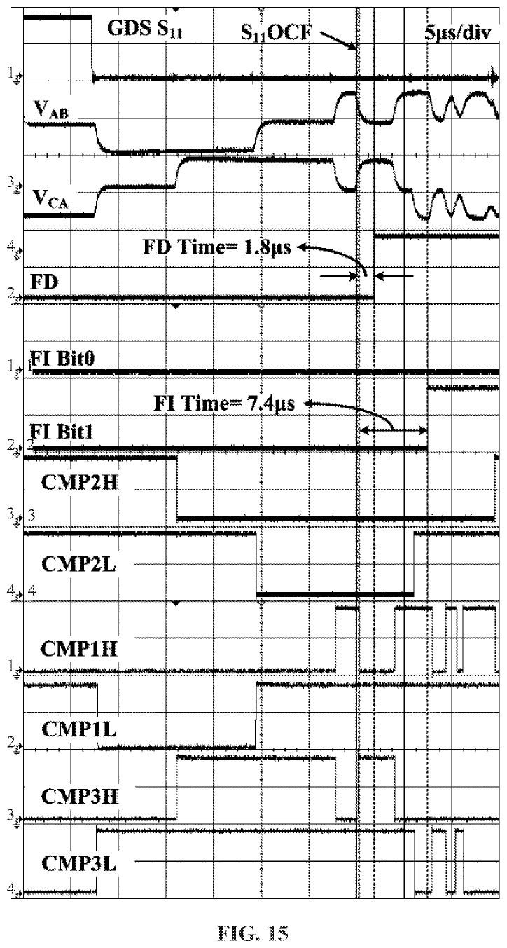

The embodiments of the present application further provide a fault determination method for a three-phase dual active bridge converter. The method may be performed by any fault determination method for a three-phase dual active bridge converter described above. FIG. 16 is a flowchart of a fault determination method for a three-phase dual active bridge converter according to an embodiment of the present application. With reference to FIG. 16, the fault determination method for a three-phase dual active bridge converter includes the following steps.

In S1601, voltages between two bridge arm switch node points on a primary side of the three-phase dual active bridge converter are acquired.

The primary side of the three-phase dual active bridge converter is provided with three bridge arms, and the connection point between two switch combinations on each bridge arm is a switch node point of the bridge arm. The three bridge arms on the primary side of the three-phase dual active bridge converter may be defined as a first bridge arm, a second bridge arm, and a third bridge arm, respectively, and then the bridge arm combinations may be a first-second bridge arm, a second-third bridge arm, and a third-first bridge arm, respectively. For example, corresponding to the bridge arm combinations, the voltages may include a first-second bridge arm voltage between the first bridge arm switch node point and the second bridge arm switch node point, a second-third bridge arm voltage between the second bridge arm switch node point and the third bridge arm switch node point, and a third-first bridge arm voltage between the third bridge arm switch node point and the first bridge arm switch node point.

In S1602, whether a fault occurs in the three-phase dual active bridge converter is determined according to a relative relationship between a sequence change of the voltages and a normal sequence change.

The sequence of the voltages refers to the sequence of a sequential combination of the first-second bridge arm voltage, the second-third bridge arm voltage, and the third-first bridge arm voltage. The normal sequence change refers to the correct change of the sequence of the voltages and is related to the change order of the on/off states of the controllable switches on the primary side of the three-phase dual active bridge converter. Whether a fault occurs in the three-phase dual active bridge converter may be determined according to whether the sequence change of the voltages matches the normal sequence change. For example, in the case of the normal sequence change, the sequence combination of the three voltages, that is, the first-second bridge arm voltage, the second-third bridge arm voltage, and the third-first bridge arm voltage, is high-zero-low (that is, the first-second bridge arm voltage is at a high potential, the second-third bridge arm voltage is at a zero potential, and the third-first bridge arm voltage is at a low potential), and then the sequence combination should change into zero-high-low. In the case of an actual sequence change, if the sequence combination of the first-second bridge arm voltage, the second-third bridge arm voltage, and the third-first bridge arm voltage changes from high-zero-low into low-high-zero, then the processing unit may determine that a fault occurs in the three-phase dual active bridge converter.

For example, in the case of the normal sequence change, the sequence combination of the three voltages, that is, the first-second bridge arm voltage, the second-third bridge arm voltage, and the third-first bridge arm voltage, is high-zero-low (that is, the first-second bridge arm voltage is at a high potential, the second-third bridge arm voltage is at a zero potential, and the third-first bridge arm voltage is at a low potential), and then the sequence combination should change into zero-high-low. In the case of an actual sequence change, if the sequence combination of the first-second bridge arm voltage, the second-third bridge arm voltage, and the third-first bridge arm voltage changes from high-zero-low into low-high-zero, then the processing unit may determine that a fault occurs in the three-phase dual active bridge converter.

In the fault determination method for a three-phase dual active bridge converter provided in this embodiment, voltages between two bridge arm switch node points on a primary side of the three-phase dual active bridge converter are acquired, and whether a fault occurs in the three-phase dual active bridge converter is determined according to a relative relationship between a sequence change of the voltage and a normal sequence change, thereby achieving the fault determination for the three-phase dual active bridge converter. Since whether a fault occurs is determined by using the voltages in the three-phase active bridge converter, no sensing element is required to be added to the converter, and the data processing function is integrated into the processing unit of the converter, thereby reducing the complexity of the fault determination circuit. Since the fault determination is performed by means of voltages, the processing of a large amount of sensing data can be avoided, thereby improving the determination speed.

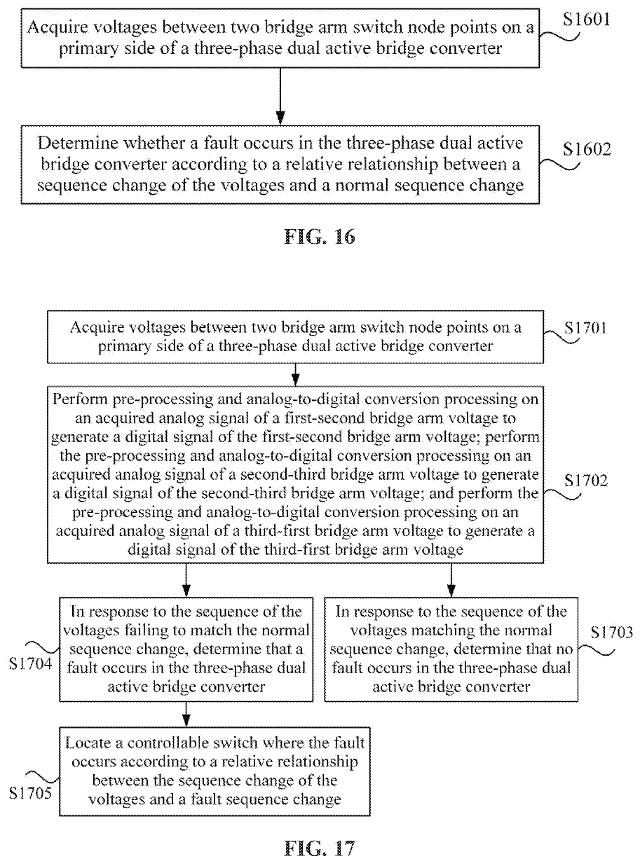

FIG. 17 is another flowchart of a fault determination method for a three-phase dual active bridge converter according to an embodiment of the present application. On the basis of the preceding embodiments, with reference to FIG. 17, the fault determination method for a three-phase dual active bridge converter includes the following steps.

In S1701, voltages between two bridge arm switch node points on a primary side of the three-phase dual active bridge converter are acquired.

The voltages include a first-second bridge arm voltage, a second-third bridge arm voltage, and a third-first bridge arm voltage.

In S1702, pre-processing and analog-to-digital conversion processing are performed on an acquired analog signal of the first-second bridge arm voltage to generate a digital signal of the first-second bridge arm voltage; the pre-processing and the analog-to-digital conversion processing are performed on an acquired analog signal of the second-third bridge arm voltage to generate a digital signal of the second-third bridge arm voltage; and the pre-processing and the analog-to-digital conversion processing are performed on an acquired analog signal of the third-first bridge arm voltage to generate a digital signal of the third-first bridge arm voltage.

The pre-processing includes attenuation processing, filtering processing, and isolation processing. The digital signal may include a two-bit binary signal. The analog signal of the first-second bridge arm voltage, the analog signal of the second-third bridge arm voltage, and the analog signal of the third-first bridge arm voltage may each be converted into a two-bit binary signal through attenuation processing, filtering processing, isolation processing, and analog-to-digital conversion processing, so there are three two-bit binary signals, that is, a six-bit binary signal. For example, when the sequence of the voltages is zero-high-low, the sequence of the voltage may be converted into a six-bit binary signal 10, 11 and 00 (or 101100), where 10 corresponds to the zero potential, 11 corresponds to the high potential, and 00 corresponds to the low potential.

In S1703, in response to the sequence of the voltages matching the normal sequence change, it is determined that no fault occurs in the three-phase dual active bridge converter.

The normal sequence change includes: the sequential combination of the first-second bridge arm voltage, the second-third bridge arm voltage, and the third-first bridge arm voltage cyclically changes from high-low-zero into high-zero-low, from high-zero-low into zero-high-low, from zero-high-low into low-high-zero, from low-high-zero into low-zero-high, from low-zero-high into zero-low-high, and from zero-low-high back into high-low-zero. If the sequence of the voltages matches the normal sequence change, it may be determined that no fault occurs in the three-phase dual active bridge converter. For example, if the sequence of the voltage changes from high-zero-low into zero-high-low according to the normal sequence change, it may be determined that no fault occurs in the three-phase dual active bridge converter.

In S1704, in response to the sequence of the voltage failing to match the normal sequence change, it is determined that a fault occurs in the three-phase dual active bridge converter.

If the sequence of the voltages fails to match the normal sequence change, it may be determined that a fault occurs in the three-phase dual active bridge converter. For example, if the sequence of the voltages does not change from high-zero-low into zero-high-low according to the normal sequence change but changes into low-high-zero, it may be determined that a fault occurs in the three-phase dual active bridge converter.

In S1705, a controllable switch where the fault occurs is located according to a relative relationship between the sequence change of the voltages and a fault sequence change.

The sequence change refers to the sequence change of the voltages after it is determined that the fault occurs in the three-phase dual active bridge converter. In the case where the fault occurs in the three-phase dual active bridge converter, the sequence change of the voltages needs to be compared to see which fault sequence change it matches, and the fault sequence change corresponds to a faulty controllable switch. In the case where the sequence change matches a fault sequence change, then the controllable switch corresponding to the fault sequence change is the faulty controllable switch, and at this time, the fault is located.

In the fault determination method for a three-phase dual active bridge converter provided by the embodiments of the present application, pre-processing and analog-to-digital conversion processing are performed on an acquired analog signal of the first-second bridge arm voltage to generate a digital signal of the first-second bridge arm voltage; the pre-processing and the analog-to-digital conversion processing are performed on an acquired analog signal of the second-third bridge arm voltage to generate a digital signal of the second-third bridge arm voltage; and the pre-processing and the analog-to-digital conversion processing are performed on to generate a digital signal of the third-first bridge arm voltage. Then, according to the digital signals, in response to the sequence of the voltages matching the normal sequence change, it is determined that no fault occurs in the three-phase dual active bridge converter operates. In response to the sequence of the voltages failing to match the normal sequence change, it is determined that a fault occurs in the three-phase dual active bridge converter. A controllable switch where the fault occurs is located according to the relative relationship between the sequence change of the voltages and a fault sequence change, thereby achieving the fault determination and localization for the three-phase dual active bridge converter. In the above process, the acquired analog voltage is converted into a digital signal, which is convenient for data processing and analysis and reduces the pressure of storing the data corresponding to the normal sequence change and the fault sequence change, thereby reducing the cost of the fault determination and improving the determination speed and the determination reliability.

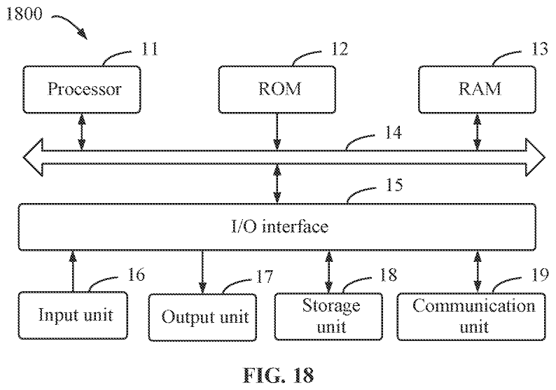

The embodiments of the present application further provide an electronic device. FIG. 18 is a structure diagram of an electronic device that may be used for implementing the embodiments of the present application. The electronic device 1800 is intended to represent various kinds of digital computers such as laptop computers, desktop computers, worktables, personal digital assistants, servers, blade servers, mainframe computers, and other suitable computers. The electronic device may further represent various kinds of mobile apparatuses such as personal digital assistants, cellular telephones, smartphones, wearable devices (such as helmets, glasses, and watches), and other similar computing apparatuses. The components shown herein, the connections and relationships thereof, and the functions thereof are used as examples only and are not intended to limit implementations of the present application described and/or claimed herein.

As shown in FIG. 18, the electronic device 1800 includes at least one processor 11 and a memory that is in a communication connection with the at least one processor 11. For example, the memory may be a read-only memory (ROM) 12 and a random-access memory (RAM) 13.

The memory stores a computer program executable by the at least one processor. The processor 11 may perform various kinds of suitable actions and processing according to a computer program stored in the ROM 12 or a computer program loaded into the RAM 13 from a storage unit 18. In the RAM 13, various kinds of programs and data needed for operations of the electronic device 1800 may also be stored. The processor 11, the ROM 12, and the RAM 13 are connected to each other via a bus 14. An input/output (I/O) interface 15 may also be connected to the bus 14.

Various components in the electronic device 1800 are connected to the I/O interface 15, including an input unit 16 such as a keyboard and a mouse; an output unit 17 such as various types of displays and loudspeakers; the storage unit 18 such as a magnetic disk or an optical disc; and a communication unit 19 such as a network card, a modem, and a wireless communication transceiver. The communication unit 19 allows the electronic device 1800 to exchange information/data with other devices through a computer network such as the Internet and/or a variety of telecommunication networks.

The processor 11 may be various kinds of general-purpose and/or special-purpose processing components that have processing and computing capabilities. Examples of the processor 11 include, but are not limited to, a central processing unit (CPU), a graphics processing unit (GPU), various kinds of special-purpose artificial intelligence (AI) computing chips, various kinds of processors running machine learning model algorithms, a digital signal processor (DSP), and any suitable processors, controllers, microcontrollers. The processor 100 performs various methods and processing described above, for example, the fault determination method for a three-phase dual active bridge converter.

In some embodiments, the fault determination method for a three-phase dual active bridge converter may be implemented as a computer program tangibly embodied on a computer-readable storage medium, for example, on the storage unit 18. In some embodiments, all or a portion of the computer program may be loaded and/or installed in the electronic device 1800 via the ROM 12 and/or the communication unit 19. When the computer program is loaded in the RAM 13 and executed by the processor 11, one or more steps of the fault determination method for a three-phase dual active bridge converter described above may be performed. Optionally, in other embodiments, the processor 11 may be configured in any other suitable manner (for example, by means of firmware) to perform the fault determination method for a three-phase dual active bridge converter.

Various implementations of the systems and techniques described above herein may be implemented in a digital electronic circuit system, an integrated circuit system, an FPGA, an application-specific integrated circuit (ASIC), an application-specific standard product (ASSP), a system on a chip (SOC), a complex programmable logic device (CPLD), computer hardware, firmware, software, and/or combinations thereof. These various implementations may include implementation in one or more computer programs that are executable and/or interpretable on a programmable system including at least one programmable processor that may be a special- or general-purpose programmable processor and may receive data and instructions from, and transmit data and instructions to, a storage system, at least one input apparatus, and at least one output apparatus.

The computer program for performing the method of the present application may be written in any combination of one or more programming languages. These computer programs may be provided for a processor of a general-purpose computer, a special-purpose computer, or other programmable data processing apparatuses such that the computer programs, when executed by the processor, cause the functions/operations specified in the flowcharts and/or block diagrams to be implemented. The computer programs may execute entirely on one machine, partly on the machine, as a stand-alone software package, partly on the machine and partly on a remote machine or entirely on the remote computer or server.

In the context of the present application, a computer-readable storage medium may be a tangible medium that can contain or store a computer program for use by or in connection with an instruction execution system, apparatus, or device. The computer-readable storage medium may be, but not limited to, an electronic, magnetic, optical, electromagnetic, infrared, or semiconductor system, apparatus, or device, or any suitable combination thereof. Optionally, the computer-readable storage medium may be a machine-readable storage medium. Examples of the machine-readable storage medium include an electrical connection based on one or more wires, a portable computer disk, a hard disk, a RAM, a ROM, an erasable programmable read-only memory (EPROM) or a flash memory, an optical fiber, a portable compact disk read-only memory (CD-ROM), an optical memory device, a magnetic memory device, or any suitable combination thereof.

To provide for interaction with a user, the systems and techniques described herein can be implemented on an electronic device having a display apparatus (for example, a cathode ray tube (CRT) or liquid crystal display (LCD) monitor) for displaying information to the user as well as a keyboard and a pointing apparatus (for example, a mouse or a trackball) by which the user can provide input for the electronic device. Other kinds of apparatuses can be used to provide for interaction with a user as well; for example, feedback provided for the user can be any form of sensory feedback (for example, visual feedback, auditory feedback, or tactile feedback); and input from the user can be received in any form (including acoustic input, speech input, or tactile input).

The systems and techniques described herein can be implemented in a computing system that includes a back-end component (for example, as a data server), or a computing system that includes a middleware component (for example, an application server), or a computing system that includes a front-end component (for example, a client computer having a graphical user interface or a Web browser through which a user can interact with an implementation of the systems and techniques described herein), or a computing system that includes any combination of such back-end, middleware, or front-end components. The components of the system can be interconnected by any form or medium of digital data communication (for example, by a communication network). Examples of the communication network include a local area network (LAN), a wide area network (WAN), a blockchain network, and the Internet.

The computing system may include a client and a server. The client and the server are generally remote from each other and typically interact through a communication network. The relationship of the client and the server arises by virtue of computer programs running on the respective computers and having a client-server relationship with each other. The server may be a cloud server which is also referred to as a cloud computing server or a cloud host. As a host product in a cloud computing service system, the server solves the defects of difficult management and poor service scalability in the service of a conventional physical host and a virtual private server (VPS).

It is to be understood that various forms of processes shown above may be adopted with steps reordered, added, or deleted. For example, the steps described in the present application may be performed in parallel, sequentially, or in different sequences, as long as the desired results of the solutions of the present application can be achieved, and no limitation is imposed herein.

1. A fault determination apparatus for a three-phase dual active bridge converter, comprising:
a signal acquisition unit connected to each of three bridge arm switch node points on a primary side of the three-phase dual active bridge converter and configured to acquire voltages between two bridge arm switch node points of the three bridge arm switch node points on the primary side; and
a processing unit connected to the signal acquisition unit and configured to determine whether a fault occurs in the three-phase dual active bridge converter according to a relative relationship between a sequence change of the voltages and a normal sequence change.

2. The fault determination apparatus according to claim 1, wherein the signal acquisition unit comprises a respective one of pre-processing units in a one-to-one correspondence with each of the voltages and a respective one of analog-to-digital conversion units in a one-to-one correspondence with each of the voltages;
for each pre-processing unit, the pre-processing unit is configured to acquire an analog signal of the respective voltage and pre-process the analog signal to obtain a pre-processed analog signal;
for each analog-to-digital conversion unit, the analog-to-digital conversion unit is separately connected to a respective pre-processing unit and the processing unit and is configured to convert the pre-processed analog signal into a digital signal and send the digital signal to the processing unit.

3. The fault determination apparatus according to claim 1, wherein,
in response to the fault occurring in the three-phase dual active bridge converter, the processing unit is further configured to determine a location where the fault occurs in the three-phase dual active bridge converter according to a relative relationship between the sequence change of the voltages and a fault sequence change, wherein the fault sequence change corresponds to a controllable switch where the fault occurs.

4. A fault determination method for a three-phase dual active bridge converter, comprising:
acquiring voltages between two bridge arm switch node points on a primary side of the three-phase dual active bridge converter; and
determining whether a fault occurs in the three-phase dual active bridge converter according to a relative relationship between a sequence change of the voltages and a normal sequence change.

5. The fault determination method according to claim 4, wherein determining whether a fault occurs in the three-phase dual active bridge converter according to a relative relationship between a sequence change of the voltages and a normal sequence change comprises:
in response to the sequence change of the voltages failing to match the normal sequence change, determining that the fault occurs in the three-phase dual active bridge converter; and
in response to the sequence change of the voltages matching the normal sequence change, determining that the fault does occurs in the three-phase dual active bridge converter.

6. The fault determination method according to claim 4, wherein,
the voltages comprises a first-second bridge arm voltage, a second-third bridge arm voltage, and a third-first bridge arm voltage; and
before determining whether the fault occurs in the three-phase dual active bridge converter according to the relative relationship between the sequence change of the voltages and the normal sequence change, the method further comprises:
performing pre-processing and analog-to-digital conversion processing on an acquired analog signal of the first-second bridge arm voltage to generate a digital signal of the first-second bridge arm voltage;
performing the pre-processing and the analog-to-digital conversion processing on an acquired analog signal of the second-third bridge arm voltage to generate a digital signal of the second-third bridge arm voltage, and
performing the pre-processing and the analog-to-digital conversion processing on an acquired analog signal of the third-first bridge arm voltage to generate a digital signal of the third-first bridge arm voltage.

7. The fault determination method according to claim 6, wherein the pre-processing comprises attenuation processing, filtering processing, and isolation processing.

8. The fault determination method according to claim 6, wherein the normal sequence change comprises: a sequential combination of the first-second bridge arm voltage, the second-third bridge arm voltage, and the third-first bridge arm voltage cyclically changes from high-low-zero into high-zero-low, from high-zero-low into zero-high-low, from zero-high-low into low-high-zero, from low-high-zero into low-zero-high, from low-zero-high into zero-low-high, and from zero-low-high back into high-low-zero.

9. The fault determination method according to claim 4, wherein after determining whether the fault occurs in the three-phase dual active bridge converter according to the relative relationship between the sequence change of the voltages and the normal sequence change, the method further comprises:
in response to the fault occurring in the three-phase dual active bridge converter, locating a controllable switch where the fault occurs according to a relative relationship between the sequence change of the voltages and a fault sequence change.

10. An electronic device, comprising:
at least one processing unit; and
a memory which is in a communication connection with the at least one processing unit;
wherein the memory stores a computer program executable by the at least one processing unit, and the computer program is executed by the at least one processing unit to enable the at least one processing unit to execute;
acquiring voltages between two bridge arm switch node points on a primary side of the three-phase dual active bridge converter; and
determining whether a fault occurs in the three-phase dual active bridge converter according to a relative relationship between a sequence change of the voltages and a normal sequence change.

11. The electronic device according to claim 10, wherein the at least one processor is configured to determine whether a fault occurs in the three-phase dual active bridge converter by
in response to the sequence change of the voltages failing to match the normal sequence change, determining that the fault occurs in the three-phase dual active bridge converter; and
in response to the sequence change of the voltages matching the normal sequence change, determining that the fault does occurs in the three-phase dual active bridge converter.

12. The electronic device according to claim 10, wherein,
the voltages comprises a first-second bridge arm voltage, a second-third bridge arm voltage, and a third-first bridge arm voltage; and
before determining whether the fault occurs in the three-phase dual active bridge converter, the at least one processor is further configured to execute:
performing pre-processing and analog-to-digital conversion processing on an acquired analog signal of the first-second bridge arm voltage to generate a digital signal of the first-second bridge arm voltage;
performing the pre-processing and the analog-to-digital conversion processing on an acquired analog signal of the second-third bridge arm voltage to generate a digital signal of the second-third bridge arm voltage, and
performing the pre-processing and the analog-to-digital conversion processing on an acquired analog signal of the third-first bridge arm voltage to generate a digital signal of the third-first bridge arm voltage.

13. The electronic device according to claim 12, wherein the pre-processing comprises attenuation processing, filtering processing, and isolation processing.

14. The electronic device according to claim 12, wherein the normal sequence change comprises: a sequential combination of the first-second bridge arm voltage, the second-third bridge arm voltage, and the third-first bridge arm voltage cyclically changes from high-low-zero into high-zero-low, from high-zero-low into zero-high-low, from zero-high-low into low-high-zero, from low-high-zero into low-zero-high, from low-zero-high into zero-low-high, and from zero-low-high back into high-low-zero.

15. The electronic device according to claim 10, wherein after determining whether the fault occurs in the three-phase dual active bridge converter, the at least one processor is further configured to execute:
in response to the fault occurring in the three-phase dual active bridge converter, locating a controllable switch where the fault occurs according to a relative relationship between the sequence change of the voltages and a fault sequence change.
